(19) United States
(12) Patent Application Publication
(10) Pub. No.: US 2025/0261299 A1
(43) Pub. Date: Aug. 14, 2025

(54) MULTI-MATERIAL THREE-DIMENSIONAL THERMAL CONDUCTIVE TRACES

(71) Applicant: MELLANOX TECHNOLOGIES, LTD., Yokneam (IL)

(72) Inventors: Ella Sanders Klein, HaSolelim (IL); Ran Hasson Ruso, Pardes Hanna-Karkur (IL); Rotem Glick Carmi, Kiryat Motzkin (IL); Elad Mentovich, Tel Aviv (IL)

(21) Appl. No.: 18/441,261

(22) Filed: Feb. 14, 2024

(51) Int. Cl. H05K 1/02; H05K 3/28

(52) U.S. Cl. CPC H05K 1/0209; H05K 3/28; H05K 2201/09909

(57) ABSTRACT

Systems and methods herein are for a printed circuit board (PCB) having open circuitry and having a three-dimensional (3D) printed material that is deposited in a single process over at least one area of the PCB, where the 3D printed material may include at least a thermally-conductive material to enable at least one thermal conductive trace by the thermally-conductive material being over an electrically-insulating material of the 3D printed material and being over the open circuitry, and where the at least one thermal conductive trace can provide heat spreading from at least one hot area of the PCB to a remote area of the PCB.

### TECHNICAL FIELD

At least one embodiment pertains to a printed circuit board (PCB) having thermal conductive traces for heat spreading and dissipation for cooling purposes.

### BACKGROUND

Electrical components, such as semiconductor products, on a printed circuit board (PCB) may be subject to overheat during usage of the PCB. This can compromise functioning of one or more individual ones of the electrical components and the PCB as a whole. The overheating may be a result of performing compute and storage operations and may be due to energy losses of electrical current of open circuitry of the PCB. The compromised functioning may be a reduction in a component's performance. Further, there may be certain types of electrical components, as well as areas on the PCB, that may be subject to thermal damaged partly due to specific functionality therein or their location, such as for being close to an overheated component with insufficient heat dissipation. For some semiconductor product, the compromised functioning may be that the underlying silicon loses its semiconductor characteristics at high temperatures. This may also lead to permanent damage that may be mechanical damage or melting of the semiconductor product or PCB areas having such hot areas of the semiconductor product. An electrical component on a PCB may have small features or may have a complex structure or arrangement of features and of circuit traces that form, in part, the open circuitry. However, the electrical components may include heat generating components or may be near heat-affected ones of the electrical components that are closely located to a heat generating component on the PCB. Application of a heat removal layer, such as a thermal interface material (TIM), may be complicated for such semiconductor products due in part to a large interface on such small components, and in part to the complex structure or arrangement.

### BRIEF DESCRIPTION OF DRAWINGS

FIG. 1 is an illustrative plan view of a printed circuit board (PCB) subject to thermal conductive traces for heat spreading by a multi-material three-dimensional (MM3D) printer, in at least one embodiment;

FIG. 2 is an illustration of MM3D printing of thermal conductive traces to a PCB, in at least one embodiment;

FIG. 3 illustrates aspects of mapping of hot areas and remote areas for MM3D printing of thermal conductive traces to a PCB, in at least one embodiment;

FIG. 4 illustrates computer and processor aspects of a MM3D printing system that supports application of a heat spreader by MM3D printing of thermal conductive traces to a PCB, according to at least one embodiment;

FIG. 5 illustrates a process flow for a heat spreader by MM3D printing of thermal conductive traces to a PCB, according to at least one embodiment;

FIG. 6 illustrates yet another process flow for a heat spreader by MM3D printing of thermal conductive traces to a PCB, according to at least one embodiment; and

FIG. 7 illustrates a further process flow for operating a PCB having a heat spreader by MM3D printing of thermal conductive traces, according to at least one embodiment.

### DETAILED DESCRIPTION

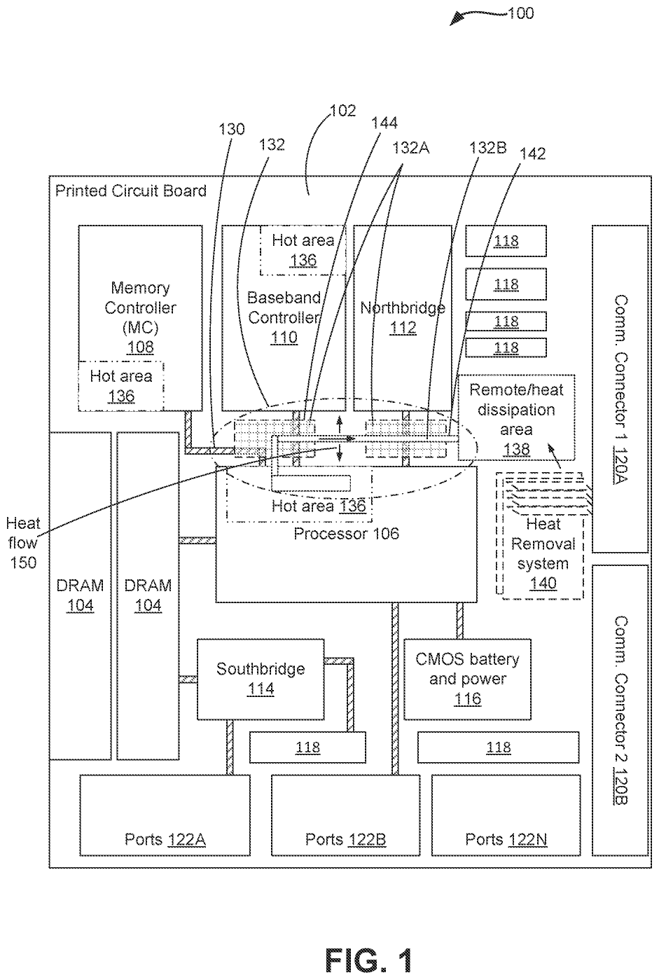

FIG. 1 is an illustrative plan view of a printed circuit board (PCB) 100 subject to thermal conductive traces for heat spreading by a multi-material three-dimensional (MM3D) printer, in at least one embodiment. The PCB 100 may include open circuitry 130 and the MM3D printed material 132 that is deposited in a single process over at least one part of the open circuitry. As used herein and in at least one embodiment, the open circuitry 130 may include one or more of integrated circuits (ICs), connection pads, and transmission lines or interconnections between the ICs. As used herein and in at least one embodiment, the open circuitry 130 may include any two points on a PCB 100 that may be subject to electrical shorting if the two points are electrically associated together.

The MM3D printed material 132 may include an electrically-insulating material 132A to prevent electrical shorting and may include a thermally-conductive material 132B thereover to allow heat flow over the electrically-insulating material 132A. The electrically-insulating material 132A may be printed as electrically insulating pads 144 over parts of the open circuitry to allow, thereon, the thermally-conductive material 132B, which altogether provide a thermal conductive trace 142. Therefore, the thermally-conductive material 132B by itself or in combination the thermally-conductive material 132B can provide a thermal conductive trace 142, even though marked the electrically insulating pads 144 is marked as a distinct feature. Further, the thermal conductive trace 142 is to pass heat or support heat flow from a hot area 136 to a remote area 138 of the PCB 100.

As used herein, the remote area 138 may be a dissipation area from where heat may be dissipated by a heat removal system 140, such as a heat sink or a cold plate. As used herein, the remote area 138 may be also referred to herein as a cold area. For example, the cold area is at least at a lower temperature relative to the hot area 136. Further, the hot area 136 may be provided by underlying compute or storage circuitry and may exist on one or more of the illustrated components 104-118 that may be semiconductor products on the PCB 100. Therefore, the remote area may be part of the PCB 100 that is devoid of any components or that has components that generate very less heat relative to the hot areas 136.

As such, the MM3D printed material, generally marked by reference numeral 132 and not including any part of the open circuitry 130, may be provided to enable a thermal conductive trace 142 by at least the thermally-conductive material 132B. The thermally-conductive material 132B may be over an electrically-insulating material 132A that forms an electrically insulating pad 144 over the at least one part of the open circuitry 130. In addition, the thermally-conductive material 132B may be applied in a single process with the electrically-insulating material 132A. Further, the at least one thermal conductive trace 142, having the thermally-conductive material 132B, is to provide heat spreading from at least one hot area 136 of the PCB 100. The heat spreading may be a directional heat flow 150, from the at least one hot area 136 to a remote area 138 of the PCB 100. This may be as a result of a temperature differential between a hot area 136 and the remote area 138. In at least one embodiment, the electrically-insulating material 132A may be parylene or polyimide. In at least one embodiment, the thermally-conductive material 132B may be graphene-flakes based composite materials, carbon nano-fibers based composite materials, silver nanoparticles based materials, or may be composite matrix polymers.

In addition, along the thermal conductive trace 142, additional heat spreading may be enabled in a lateral direction, which is represented by the side arrows of the heat flow 150. The MM3D printed material 132 is also conformal over any of the features, including semiconductor products, on the surface 102 of the PCB 100. Further, it is possible that the remote area 138 is on another semiconductor product of the PCB 100 that is either used lesser than a semiconductor product generating heat or is a less compute or storage-intensive component of the PCB 100.

In at least one embodiment, the MM3D printed material 132 applied to a PCB herein is able to address heat removal that may otherwise be limited to heat transfer from a semiconductor product to an external heat sink or cold plate using a heat-conducing thermal interface material (TIM) that is applied to a surface of the semiconductor product. For example, a heat-conducing TIM may be electrically conductive and may not be suited for application around open circuitry, such as connection pads and thermal conductive traces. Further, heat may be transferred, in a vertical manner, to a heat removal system, such as a heat sink or cold plate. In addition, heat removal systems may include air cooling and liquid cooling. However, the heat removal system may also include the TIM that may cause mechanical warp of the PCB due, in part, to the TIM's properties and being spread over the entire semiconductor product. Moreover, the TIM may require a flat surface and, therefore, a specific topography over the semiconductor product in the PCB may be a further requirement. In one example, any non-uniform topography may incorporate voids of air upon application of the TIM. The voids provide gaps around the topology of small features that may not filled and that may result in a decreased heat removal efficiency and may subsequently lead to decreased performance of semiconductor products.

Therefore, among the many benefits of the MM3D printed material 132 on a PCB 100, is its ability to be applied selectively over small features of the PCB 100 and to be applied to cover a certain area of a PCB 100 that may include hot areas 136 requiring heat spreading and, subsequently, heat dissipation. This removes from any requirement to cover large areas of a semiconductor product or the PCB. Further, the MM3D printed material 132 allows, which providing thermal conductive traces 142 allows for heat spreading using such thermal conductive traces 142. The heat spreading can remove heat laterally and can allows better spreading of heat over the PCB 100. This may be in addition to being able to support intelligent transfer of the heat in a suitably designed route that is mapped to the PCB 100 and that is enabled by the thermal conductive traces 142. Further, the thermal conductive traces 142 may be over the PCB and may be over the semiconductor product. The thermal conductive traces 142 may be from a hot semiconductor product (encompassing a hot area or a total area of the semiconductor product) in a conformal manner, and may be towards a heat removal system. Therefore, heat is spread laterally rather than purely in a vertical manner. In at least one embodiment, the MM3D printed material 132 on a PCB 100 enables the use of local and small-sized 3D cooling fins as a heat removal system to overlay a thermal conductive trace 142, instead of a TIM that is merely a heat transfer layer.

The MM3D printed material 132 on a PCB 100 also addresses limitations in heat removal methods or heat transfer applications by providing an electrically-insulating material where needed to prevent an electrical shorting during application of a thermal conductive trace. The electrically-insulating material may be provided with a thermally-conductive material that overlays the electrically-insulating material for heat spreading, in a single process. In addition, as both materials are available in the single process, it is possible to only provide the thermally-conductive material in areas of the PCB that are not subject to electrical shorting. As the thermal conductive trace 142 is conformal, the electrically-insulating material and the thermally-conductive material are both conformal. Both these materials can be applied in a high resolution and over small features of the PCB, such as a small footprint of a semiconductor product.

Still further, the thermal conductive trace that is provided by the MM3D printed material 132 directs heat towards a heat removal system by a temperature differential that enables directional heat spreading. In this way, in contrast to TIMs, the thermal conductive trace performs both, as a selective application based in part on a design or map to cover small features in a conformal manner, and as a heat spreader application for hot areas to laterally spread heat prior to a heat removal system. The MM3D printed material 132 may be also used to increase a surface area of the hot area on a semiconductor product or through other areas of the PCB. In one example, it is possible to print a mini heat sink using the MM3D printed material 132. The mini heat sink may be printed as a structure of a base of the thermally-conductive material and having thereon small fins composed of the same thermally-conductive material, on a specific area of the PCB. This mini heat sink can remove heat locally, instead of by a copper or other-based heat sink.

In addition, the small fins of the mini heat sink can be directed according to a required thermal management that may be part of the heat removal system or part of the MM3D printer system herein. As the electrically-insulating material and the thermally-conductive material are conformally applied in a single process, the MM3D printer system herein uses one or more printing head to provide both materials in the single process. Further, the electrically-insulating material may be applied as electrically insulating pads 144 over open circuitry 130, including conductive traces or conductive areas, where a thermal conductive trace 142 is mapped to pass. This helps prevent electrical shortage in the open circuitry. The thermal conductive traces 142 can be printed with underlying electrically insulating pads 144 of the electrically-insulating material and overlying thermally-conductive material as thinner lines, relative to at least a width of the electrically-insulating material, on the PCB 100. In at least one embodiment, one or more aspects of the MM3D printed material 132 herein may be applied postproduction of the PCB 100 or at any stage of the production of the PCB 100. Therefore, adaptive or dynamic thermal management can be achieved for existing PCBs with no need for a new design using the MM3D printed material 132 herein.

In FIG. 1 the one or more components 104-122N may include DRAM slots 104 that may include a DRAM module, a processor 106, a memory controller (MC) 108, a baseband controller 110, a northbridge 112, a southbridge 114, a CMOS battery and power component 116, miscellaneous electrical or computer components 118, communication connectors 1 and 2 120A, 120B, and multiple device and communication ports 122A-122N. The processor 106 may be multi-core processor and may be a central processing unit (CPU), a graphics processing unit (GPU), or a data processing unit (DPU). There may be multiple processors 106 instead of the one illustrated. Each of the multi-cores may be heat generating and may be a separate hot area 136, of which, one or a group is illustrated on the processor 106 in FIG. 1

The memory controller (MC) 108 may include circuitry to manage flow of data between a main memory and other devices on a PCB 100. In an example, the MC 108 may have the ability to execute memory commands to control timing of data transfers, and to control any error handling and correction. In one example, the MC 108 may be integrated into another semiconductor product as part of a same die or package. As the MC 108 may include execution capability, it may also include one or more hot areas 136. Therefore, the PCB 100 may include non-planar surfaces represented by the different heights of the components and may include and embedded components, such as within an MC 108 and a processor 106, that may be taken as including a planar surface of a same height, for instance.

The baseband controller 110 is a further integrated circuit of the PCB 100 and may be a communications hub of the PCB 100. The baseband controller can processes uplink and downlink data traffic, and can manage or control a remote radio unit of the PCB 100. The baseband controller 110 may be part of a network interface card (NIC) that manages all the radio functions of the PCB 100. As such, during communications, the baseband controller 110 may be subject to its own hot areas 136.

A northbridge 112 and a southbridge 114 may be provided as distinct integrated circuits on the PCB 100 to handle different communication requirements of the PCB 100. For example, the northbridge 112 may be coupled directly to processor 106. However, the southbridge 114 may not have such a direct coupling. While the northbridge 112 may be provided to handle high-speed communication between the processor 106 and standard memory or graphics processors, it may be also used to support high-bandwidth devices memory devices like solid state devices, GPUs, and DRAM. The southbridge 114 may be provided to handle lower-speed communication, relative to the northbridge 112. The lower-speed communication may include input/output (I/O) operations and device connections for hard disk drives (HDD), universal serial bus (USB®) devices, and audio or microphone interfaces. Further, the southbridge 114 can be used to support lower-bandwidth devices like SATA® drives, PCI® slots, USB ports, and basic input-output system (BIOS) of the PCB 100.

The CMOS battery and power component 116 may support startup and functioning of the PCB 100. The CMOS battery may power the BIOS, in one example, whereas the power component supports full functionality or operation of the PCB 100. The CMOS battery may be a lithium button battery to provide power to a CMOS chip having the BIOS on the PCB 100. In one instance, it can power the CMOS chip to retain the settings therein. There may be other miscellaneous electrical or computer components 118 in the PCB 100. These may include memory, additional processors, resistors, capacitors, inductors, transistors, sensors, and smaller integrated circuits (or semiconductor products) to function as controllers, for instance. There may be communication connectors 1 and 2 120A, 120B for the SATA, PCI, USB, and other communication protocols. The multiple device and communication ports 122A-122N may be used for HDMI®, DVI®, audio, video, and serial and parallel ports. The MM3D printing of thermal conductive traces to a PCB 100 must incorporate hot areas from one or more of such components 104-122N, and must be provided to overlay any open circuitry associated with these components 104-122N.

While FIG. 1 illustrates the MM3D printed material 132 provided to enable a thermal conductive trace 142 by at least the thermally-conductive material 132B that may be over an electrically-insulating material 132A for at least one hot area 136 of a processor 106, there may be other hot areas 136 that use other thermal conductive traces, that are not illustrated. These other thermal conductive traces may be from one or more of the other semiconductor products of the PCB 100 to the same or to a different remote area 138. Therefore, all or some of these thermal conductive traces may overlap or join together and may end at one or more remote areas on the PCB. Further, all or some of these thermal conductive traces may overlap or join together and may end at one or more heat removal systems on the PCB.

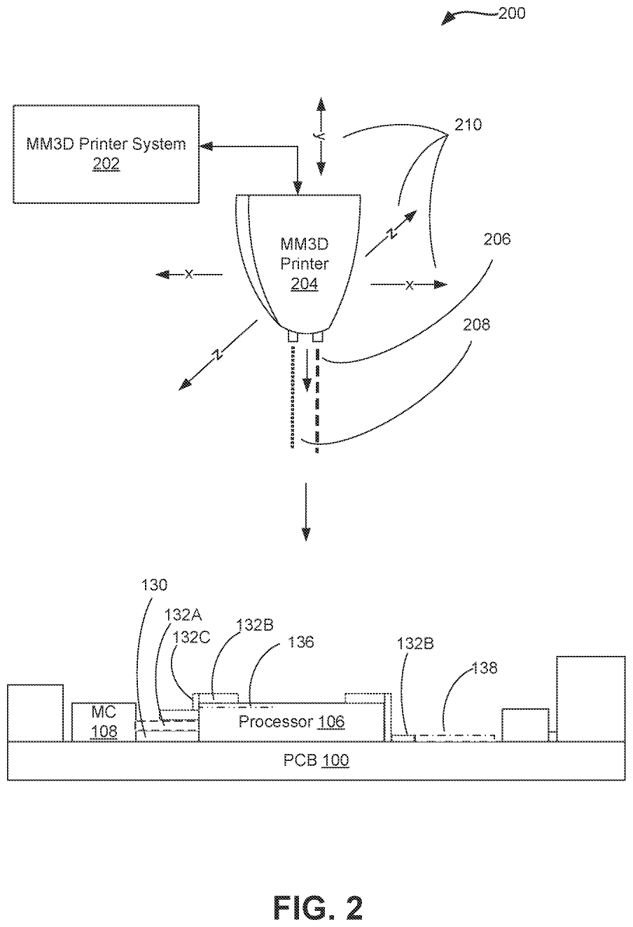

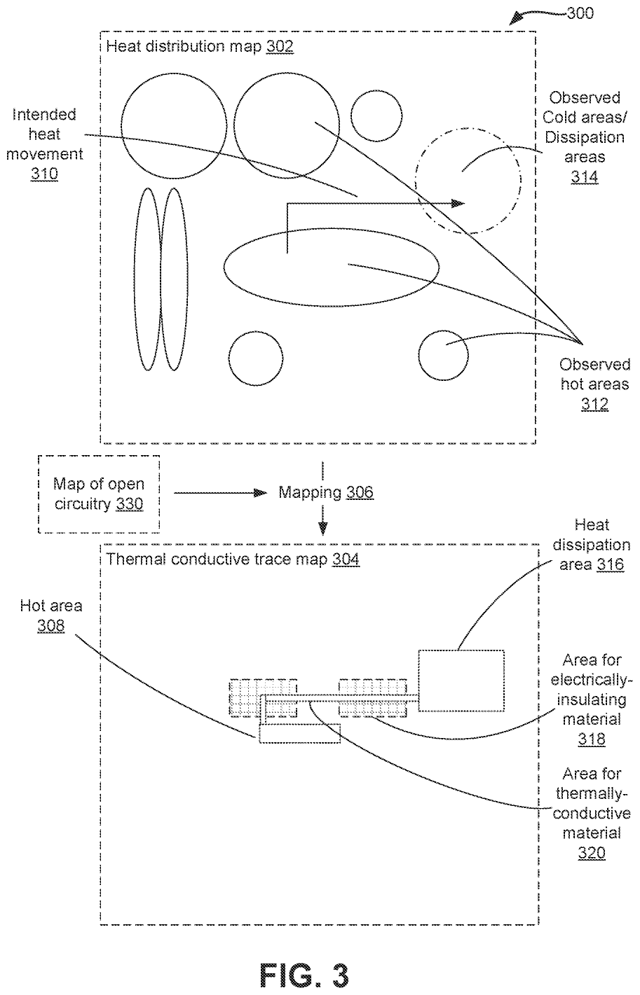

FIG. 2 is an illustration of MM3D printing 200 of thermal conductive traces to a PCB, in at least one embodiment. A MM3D printer system 202 is coupled to a MM3D printer 204 to enable the MM3D printer 204 to move according to a predetermined thermal conductive trace map of the at least one hot area 136 of the PCB 100 to a remote area 138 of the PCB 100. Although illustrated in the depth dimension, the at least one hot area 136 of the PCB 100 is on a surface of a processor 106 of the PCB 100. Further, the thermal conductive trace map may be as provided from aspects 300 of the mapping described with respect to FIG. 3.

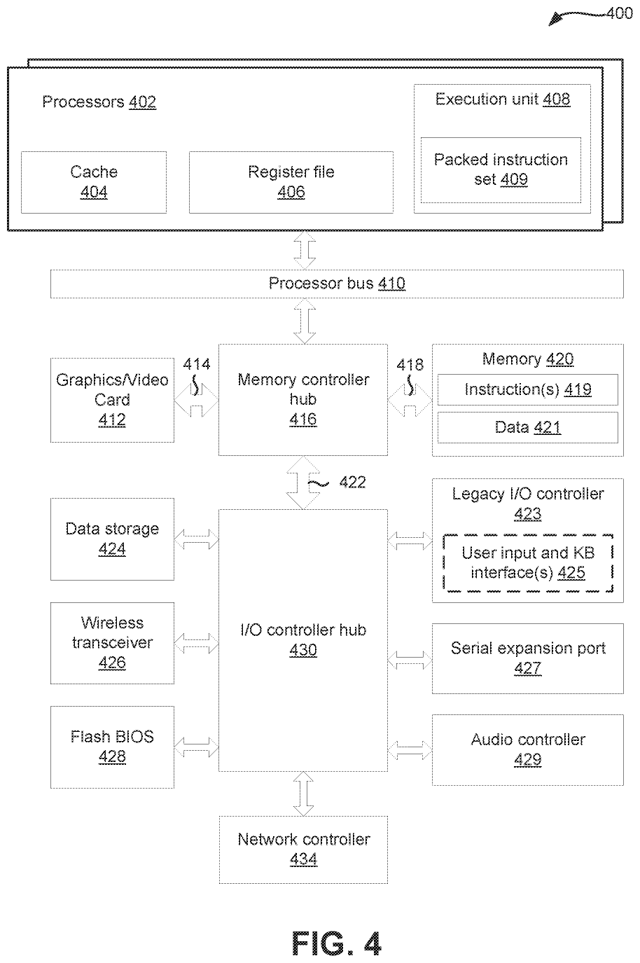

In at least one embodiment, the MM3D printer system 202 may include computer and processor aspects, as described with respect to FIG. 4. The MM3D printer system 202 is enabled to receive inputs, as described with respect to FIG. 3, that may be a map of open circuitry of a PCB 330 and that may be a heat distribution map 302 for the PCB. The map of open circuitry of a PCB 330 may be provided from blue prints used to prepare the PCB. The heat distribution map 302 may be provided from observations or monitoring processes associated with a sample of the PCB performing a stress algorithm to stress one or more of the components 104-122N to cause one or more of these components to generate maximum heat.

A thermal conductive trace map 304 may be provided from the maps 302, 330, received in the MM3D printer system 202. The thermal conductive trace map 304 may include areas to place parts of the thermal conductive trace. For example, there may be a hot area 308 defined, which may be based in part on the observed hot areas 312 of the heat distribution map 302. There may be a heat dissipation area 316 defined, which may be based in part on the observed cold or dissipation areas 314 of the heat distribution map 302. This information may be used to determine intended heat movement 310, by at least a temperature differential in the areas 312, 314 observed for the PCB 100.

In at least one embodiment, based in part on the intended heat movement 310, a path or route for the thermal conductive trace may be determined and that may be between the hot area 308 and the heat dissipation area 316 that is remote from the hot area. The thermal conductive trace may be enabled by the MM3D printer system 202 causing the MM3D printer 204 to move at least to the hot area 308 on the map 304, corresponding to the physical hot area 136 on the processor 106. The MM3D printer system 202 causes the MM3D printer 204 to print at least one part of the thermal conductive trace 142. The one part of the thermal conductive trace 142 may be only the thermally-conductive material to receive heat from the hot area 136.

Further, the MM3D printer system 202 also causes the MM3D printer 204 to move to any underlying open circuitry 130 that is between the hot area 308 on the map 304, corresponding to the physical hot area 136 on the processor 106, and the dissipation area 316, corresponding to the physical dissipation or remote area 138 on the PCB 100. The MM3D printer system 202 causes the MM3D printer 204 to print an electrically-insulating material 132A over the open circuitry 130. The MM3D printer system 202 causes the MM3D printer 204 to additionally print the thermally-conductive material 132B over the electrically-insulating material 132A, as part of the single process. The thermally-conductive material 132B that is over the hot area 136 is also associated to the thermally-conductive material 132B that is over the electrically-insulating material 132A. This allows the intended heat movement 310 to physically occur using the thermally-conductive material 132B.

In at least one embodiment, therefore, the MM3D printer 204 is configured to receive an electrically-insulating material and a thermally-conductive material, and is able to provide, as a single process, the thermally-conductive material 208 and the electrically-insulating material 206 from one or more printer heads illustrated in the MM3D printer 204. The MM3D printer 204 is able to move in the x, y, and the z-axis 210 to cause the thermally-conductive material 208 and the electrically-insulating material 206 to print on the PCB 100. This allows formation or printing of the electrically-insulating material 132A over the open circuitry 130 and to formation or printing of the thermally-conductive material 132B over the hot areas, the dissipation areas, and to provide the thermal conductive traces of the PCB 100. Further, although illustrated as having distinct provisions for the thermally-conductive material 208 and an electrically-insulating material 206, the MM3D printer 204 may have a single provision that is switched internally to provide the thermally-conductive material 208 or the electrically-insulating material 206, as required by a thermal conductive trace map of FIG. 3, in at least one embodiment. The switch between the thermally-conductive material 208 and the electrically-insulating material 206 may occur at high speeds to support any printing requirement for both materials to be overlaid on the PCB as distinct materials in a single process, for instance.

In at least one embodiment, FIGS. 1 and 2, therefore illustrate a PCB 100 that has open circuitry 130 and that has at least one part of an MM3D printed material 132, such as from a thermally-conductive material 208 and an electrically-insulating material 206, that is available to be deposited in a single process over at least one area of the PCB 100. In one example, in FIG. 2, the thermally-conductive material 132B is formed over the PCB 100, in an area that are devoid of any open circuitry 130, such as adjacent to the dissipation area 138. For reference, however, the thermally-conductive material 132B alone still represents a thermal conductive trace 142 even when having only the thermally-conductive material and without the electrically-insulating material 132A, so long as it is provided as the at least one part of the 3D printed material 206, 208 in a single process and so long as it is provided to perform heat spreading described throughout herein.

Therefore, in at least one embodiment, the thermally-conductive material 132B represents at least one part of a MM3D printed material 132 that is deposited in a single process over at least one area of the PCB. The one part of the MM3D printed material 132 includes the thermally-conductive material 132B, where the MM3D printed material 132 is to enable a thermal conductive trace 142 by the thermally-conductive material 132B being over an electrically-insulating material 132A of the MM3D printed material 132 and over the open circuitry 130. Further, the thermal conductive trace 142 is to provide heat spreading from at least one hot area 136 of the PCB 100 to a remote area 138 of the PCB 100.

In at least one embodiment, the MM3D printed material 132 may include an electrically-insulating material 132A and a thermally-conductive material 132B together in other parts of the PCB 100, such as between the processor 106 and the MC 108. Therefore, in at least one embodiment, the MM3D printed material 132 is to enable at least one thermal conductive trace 142 by the thermally-conductive material 132B over the electrically-insulating material 132A and the at least one area of the open circuitry 130. The at least one thermal conductive trace 312B is to provide heat spreading from at least one hot area of the PCB to a remote area of the PCB.

Further, one or more of the remote area 138 or the thermal conductive trace 142 can expand a surface area of the heat spreading. However, one or more of the remote area 138 or the thermal conductive trace 142 allow heat dissipation using a heat removal system that may be a heat sink or a cold plate that can be associated with the remote area 138. Alternatively, the heat removal system is a mini heat sink that is enabled by a base structure and by fins formed of the thermally-conductive material 132B in the remote area 138.

FIGS. 1 and 2 also illustrate that the thermal conductive trace 142 is conformal over one or more features or components 104-118 that may include non-planar surfaces and embedded components within a planar surface on the PCB 100. In one example, an embedded component that is within a planar surface and that is provided with a partly vertical thermal conductive trace 132C may have its heat directed from a surface of the PCB 100 to above the embedded component. As such, one or more of the electrically-insulating material 132A and the thermally-conductive material 132B (including for the vertical thermal conductive trace 132C) may be conformal. In at least one embodiment, the electrically-insulating material 132A of the single process is over at least one electrically-conductive feature of the open circuitry, such as a conductive trace or connection pads of the open circuitry. This prevents short circuit of the open circuitry. The thermally-conductive material is, therefore, over the electrically-insulating material. Further, in the same PCB, there may instances of the thermally-conductive material of the single process being over at least one non-electrically conductive feature of the PCB 100 and being devoid of the electrically-insulating material there under because there is no possibility of short circuit in the absence of the open circuitry.

Further, FIGS. 1 and 2 illustrate that there may be at least one heat sink or other heat removal system 140 that may be associated with the at least one thermal conductive trace 142. The at least one heat sink may be printed by the same thermally-conductive material 132B and may be devoid of the electrically-insulating material 132A, using the single process that is used to provide the thermal conductive trace 142. Still further, an insulating polymer or non-polymer, such as a ceramic, may be used to form the electrically-insulating material. Therefore, the insulating polymer or non-polymer is adapted for printing from an MM3D printer 204. A conductive particle composite may be used to form the thermally-conductive material. The polymer and the conductive particle composite may be provided in respective chambers or areas of the MM3D printer 204.

FIG. 3 illustrates aspects 300 of mapping of hot areas and remote areas for MM3D printing of thermal conductive traces to a PCB, in at least one embodiment. As detailed with respect to FIG. 2, FIG. 3 illustrates a heat distribution map 302 provided from a stress algorithm performed of the PCB 100 or of one or more of its components 104-118. In at least one embodiment, the heat distribution map 302 may be generated based on input from each of the components 104-118 without having to perform the stress algorithm. The observed hot areas 312 may be used as a basis to generate a thermal conductive trace map 304. For example, thermal conductive traces may be determined to be placed between one or more hot areas 308 to one or more observed cold areas or dissipation areas 314. As in the case of the hot areas, the one or more observed cold areas or dissipation areas may be determined without a need for a stress algorithm, by identifying open areas on the PCB 100, for instance.

A further map of open circuitry 330 may be used with the heat distribution map 302 to determine the thermal conductive traces for the thermal conductive trace map 304. The map of open circuitry 330 may be provided from a blueprint of the PCB 100 or may be generated based in part on imaging performed for the PCB 100 to identify electrically conductive traces, connection points, and the like. Once the open circuitry, the hot areas, and the cold areas are determined, the thermal conductive trace map 304 may be generated to maximize heat spreading and usage of the areas of the PCB. In at least one embodiment, the thermal conductive trace map 304 is a mapping 306 to the heat distribution map 302 and may incorporate aspects of the map of open circuitry 330 of the PCB 100. As such, the thermal conductive trace map 304 may include areas for thermal conductive traces, and particularly, areas for electrically-insulating material 318 and areas for the thermally-conductive material 320. The thermal conductive trace map 304 may be provided to the MM3D printer system 202 to cause the MM3D printer 204 to print the thermal conductive trace 142.

FIG. 4 illustrates computer and processor aspects 400 of a MM3D printing system that supports application of a heat spreader by MM3D printing of thermal conductive traces to a PCB, according to at least one embodiment. For example, each of the illustrated processors 402 may include one or more processing or execution units 408 that can perform any or all of the features of the MM3D printing system. The MM3D printing system may include a human interface to receive one or more of the maps 302, 330. However, the MM3D printing system herein can automatically monitor a sample PCB, can automatically generate the heat distribution map, and can automatically cause the MM3D printing to be performed.

In at least one embodiment, the automation may be performed by one part of the computer and processor aspects 400 that performs a stress algorithm for a sample PCB. The automation may be further performed using another part of the computer and processor aspects 400 that performs an observation or a monitoring for a PCB performing the stress algorithm, to generate a heat distribution map for the PCB. The automation is still further performed by a mapping part of the computer and processor aspects 400 that generates the thermal conductive trace map, from the heat distribution map 302 and from the map of open circuitry 330.

The processing or execution units 408 may include multiple circuits to support the automation described herein and the interface described herein. In at least one embodiment, the processors 402 may include CPUs, GPUs, DPUs that may be associated with a multi-tenant environment to perform one or more of the transfer application features described herein. Further, the GPUs may be distinctly in distinct graphics/video cards 412, relative to a DPU (represented by a network controller 434) and a CPU represented by the processors 402 illustrated in FIG. 4. Therefore, even though described in the singular, the graphics/video card 412 may include multiple cards and may include multiple GPUs on each card.

The computer and processor aspects 400 may be performed by one or more processors 402 that include a system-on-a-chip (SOC) or some combination thereof formed with a processor that may include execution units to execute an instruction, according to at least one embodiment. In at least one embodiment, the computer and processor aspects 400 may include, without limitation, a component, such as a processor 402 to employ execution units 408 including logic to perform algorithms for process data, in accordance with present disclosure, such as in embodiment described herein. In at least one embodiment, the computer and processor aspects 400 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, the computer and processor aspects 400 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, the computer and processor aspects 400 may include, without limitation, a processor 402 that may include, without limitation, one or more execution units 408 to perform aspects according to techniques described with respect to at least one or more of FIGS. 1-3 and 5-7 herein. In at least one embodiment, the computer and processor aspects 400 is a single processor desktop or server system, but in another embodiment, the computer and processor aspects 400 may be a multiprocessor system.

In at least one embodiment, the processor 402 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, a processor 402 may be coupled to a processor bus 410 that may transmit data signals between processors 402 and other components in computer and processor aspects 400.

In at least one embodiment, a processor 402 may include, without limitation, a Level 1 (“L1”) internal cache memory (“cache”) 404. In at least one embodiment, a processor 402 may have a single internal cache or multiple levels of internal cache. In at least one embodiment, cache memory may reside external to a processor 402. Other embodiments may also include a combination of both internal and external caches depending on particular implementation and needs. In at least one embodiment, a register file 406 may store different types of data in various registers including, without limitation, integer registers, floating point registers, status registers, and an instruction pointer register.

In at least one embodiment, an execution unit 408, including, without limitation, logic to perform integer and floating point operations, also resides in a processor 402. In at least one embodiment, a processor 402 may also include a microcode (“ucode”) read only memory (“ROM”) that stores microcode for certain macro instructions. In at least one embodiment, an execution unit 408 may include logic to handle a packed instruction set 409.

In at least one embodiment, by including a packed instruction set 409 in an instruction set of a general-purpose processor, along with associated circuitry to execute instructions, operations used by many multimedia applications may be performed using packed data in a processor 402. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, an execution unit 408 may also be used in microcontrollers, embedded processors, graphics devices, DSPs, and other types of logic circuits. In at least one embodiment, the computer and processor aspects 400 may include, without limitation, a memory 420. In at least one embodiment, a memory 420 may be a Dynamic Random Access Memory (“DRAM”) device, a Static Random Access Memory (“SRAM”) device, a flash memory device, or another memory device. In at least one embodiment, a memory 420 may store instruction(s) 419 and/or data 421 represented by data signals that may be executed by a processor 402.

In at least one embodiment, a system logic chip may be coupled to a processor bus 410 and a memory 420. In at least one embodiment, a system logic chip may include, without limitation, a memory controller hub (“MCH”) 416, and processors 402 may communicate with MCH 416 via processor bus 410. In at least one embodiment, an MCH 416 may provide a high bandwidth memory path 418 to a memory 420 for instruction and data storage and for storage of graphics commands, data, and textures. In at least one embodiment, an MCH 416 may direct data signals between a processor 402, a memory 420, and other components in the computer and processor aspects 400 and to bridge data signals between a processor bus 410, a memory 420, and a system I/O interface 422. In at least one embodiment, a system logic chip may provide a graphics port for coupling to a graphics controller. In at least one embodiment, an MCH 416 may be coupled to a memory 420 through a high bandwidth memory path 418 and a graphics/video card 412 may be coupled to an MCH 416 through an Accelerated Graphics Port (“AGP”) interconnect 414. In at least one embodiment, the graphics/video card 412 may be coupled to one or more of the processors 402 via a PCIe interconnect standard. Similarly, a network controller 424 may also be coupled to one or more of the processors 402 via a PCIe interconnect standard.

In at least one embodiment, the computer and processor aspects 400 may use a system I/O interface 422 as a proprietary hub interface bus to couple an MCH 416 to an I/O controller hub (“ICH”) 430. In at least one embodiment, an ICH 430 may provide direct connections to some I/O devices via a local I/O bus. In at least one embodiment, a local I/O bus may include, without limitation, a high-speed I/O bus for connecting peripherals to a memory 420, a chipset, and processors 402. Examples may include, without limitation, an audio controller 429, a firmware hub (“flash BIOS”) 428, a wireless transceiver 426, a data storage 424, a legacy I/O controller 423 containing user input and keyboard interface(s) 425, a serial expansion port 427, such as a Universal Serial Bus (“USB”) port, and a network controller 434. In at least one embodiment, data storage 424 may comprise a hard disk drive, a floppy disk drive, a CD-ROM device, a flash memory device, or other mass storage device.

In at least one embodiment, FIG. 4 illustrates computer and processor aspects 400, which includes interconnected hardware devices or “chips”, whereas in other embodiments, FIG. 4 may illustrate an exemplary SoC. In at least one embodiment, devices illustrated in FIG. 4 may be interconnected with proprietary interconnects, standardized interconnects (e.g., PCIe) or some combination thereof. In at least one embodiment, one or more components of the computer and processor aspects 400 that are interconnected using compute express link (CXL) interconnects.

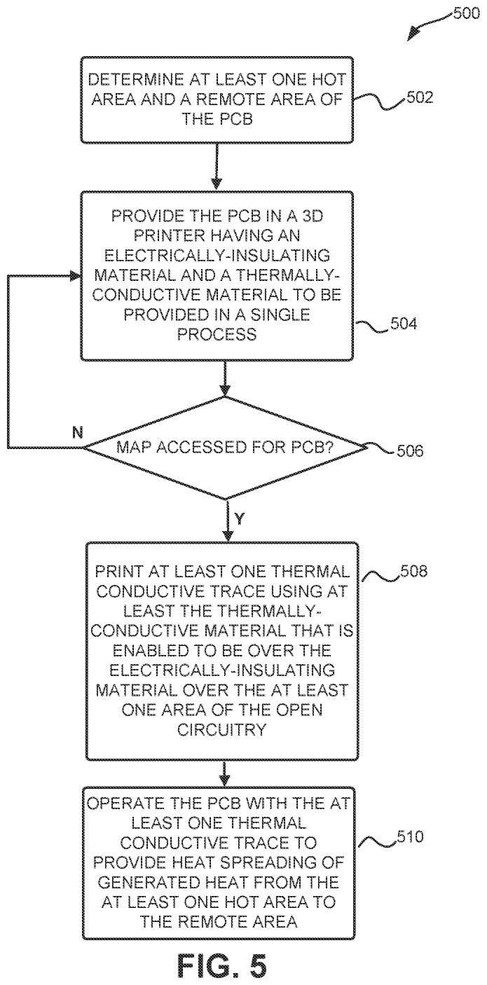

FIG. 5 illustrates a process flow or method 500 for a heat spreader by MM3D printing of thermal conductive traces to a PCB, according to at least one embodiment. The method 500 includes determining 502 at least one hot area and a remote area of the PCB. The method 500 includes providing 504 the PCB in a 3D printer which has an electrically-insulating material and a thermally-conductive material to be provided in a single process. In at least one embodiment, a thermal conductive trace map may be accessed or generated, as part of the method 500, using a heat distribution map and using a map of open circuitry for the PCB. Therefore, a step 506 in the method 500 includes verifying or determining 506 that thermal conductive trace map is pertinent to the PCB at issue.

The method 500 includes, using the 3D printer and as part of the single process, printing 508 at least one thermal conductive trace using at least one part of the 3D printed material. The one part of the 3D printed material may be the thermally-conductive material alone that may part of the at least one thermal conductive trace and that is enabled to be over the electrically-insulating material in at least one area of the open circuitry. However, the at least one thermal conductive trace may include both, the thermally-conductive material and the electrically-insulating material of the 3D printed material, with the thermally-conductive material being over the electrically-insulating material. For example, the open circuitry of the PCB may have both materials thereon forming the thermal conductive trace, whereas non-electrically conductive parts of the PCB may have only the thermally-conductive material thereon forming the thermal conductive trace. The method 500 includes operating 510 the PCB so that at least one thermal conductive trace may be to provide heat spreading of the generated heat from the PCB, from the at least one hot area of the PCB to the remote area of the PCB.

The method 500 may include a further step or may include a sub-step in which the thermal conductive trace has the thermally-conductive material along with the electrically-insulating material, from the single process, over areas of the PCB that comprise the open circuitry. While this may be enabled in step 508 of the method 500, the further step or sub-step herein ensures that both, the thermally-conductive material and the electrically-insulating material, are provided at least in areas having open circuitry so that there is no electrical shorting in those areas.

The method 500 may include a further step or may include a sub-step in which the remote area and the at least one thermal conductive trace are to expand a surface area of the heat spreading or are to allow heat dissipation using a heat removal system. The method 500 may include a further step or may include a sub-step in which the thermal conductive trace is conformal over one or more features that includes non-planar surfaces on the PCB or may include embedded components within planar surfaces on the PCB.

The method 500 may include a further step or may include a sub-step for printing, using the 3D printer and as part of the single process, the electrically-insulating material over at least one electrically-conductive feature of the open circuitry. This is so that the thermally-conductive material is over the electrically-insulating material. This printing may be done also with printing the thermally-conductive material over at least one non-electrically conductive feature of the PCB, in the single process. The printing of the thermally-conductive material over the at least one non-electrically conductive feature is devoid of the electrically-insulating material there under. Therefore, the single process can provide a thermal conductive trace over electrically-conductive features as well as non-electrically conductive feature of the open circuitry. The method 500 may include a further step or may include a sub-step for printing, using the 3D printer and as part of the single process, at least one heat sink that is associated with the at least one thermal conductive trace. The at least one heat sink may include the thermally-conductive material and may be devoid of the electrically-insulating material in the single process. This heat sink may be a mini heat sink and may be deployed in limited spaces on the PCB.

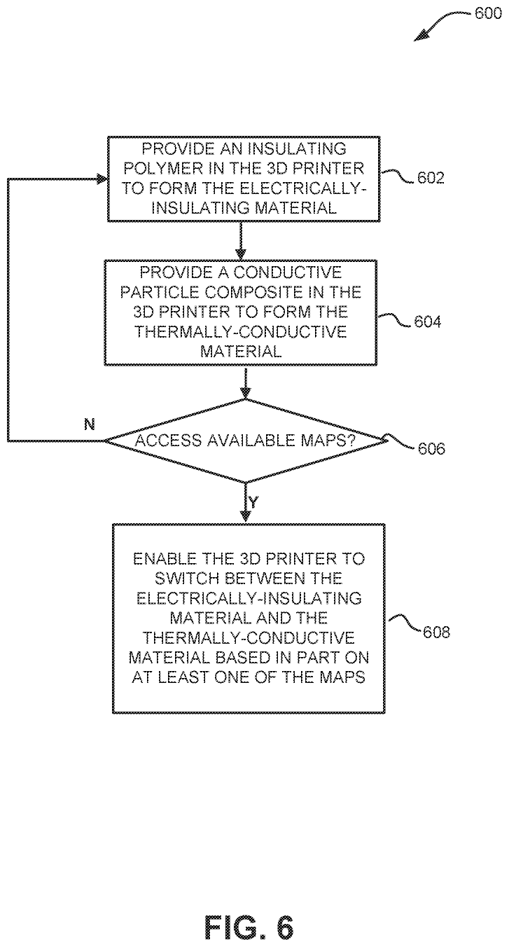

FIG. 6 illustrates yet another process flow or method 600 for a heat spreader by MM3D printing of thermal conductive traces to a PCB, according to at least one embodiment. The method 600 of FIG. 6 may be used with the method 500 of FIG. 5. For example, the method 600 includes providing the materials to enable the printing step 508 of the method 500 of FIG. 5. Further, the method 600 may be a method for manufacturing a PCB having open circuitry and the MM3D printed material thereon. The method 600 includes providing 602 an insulating polymer in the 3D printer to form the electrically-insulating material and includes providing 604 a conductive particle composite in the 3D printer to form the thermally-conductive material. The method 600 includes accessing 606 the available maps, as in the step 506 of FIG. 5. The method 600 includes enabling 608 the 3D printer to switch between the electrically-insulating material and the thermally-conductive material, based in part on at least one of the maps that has the features on the PCB that has the open circuitry.

For example, as described with respect to FIG. 3, a thermal conductive trace map may be provided from a heat distribution map and an open circuitry map for a PCB. The thermal conductive trace map may be stored for access to prepare the thermal conductive trace for similar or the same PCBs that are associated with the access map. The thermal conductive trace map is accessed or stored in the MM3D printer system. The thermal conductive trace map may include areas of the PCB to place parts of the thermal conductive trace. These areas may correspond to the features on the PCB that has the open circuitry, for instance. In one example, there may be a hot area defined, which may be based in part on the observed hot areas of the heat distribution map. There may be a heat dissipation area defined, which may be based in part on the observed cold or dissipation areas of the heat distribution map. This information, along with the open circuitry information, may be used to determine intended heat movement, by at least a temperature differential in the areas observed for the PCB. The printing may be provided to prevent short circuit in the open circuitry by the electrically-insulating material and to allow heat spreading by the thermally-conductive material.

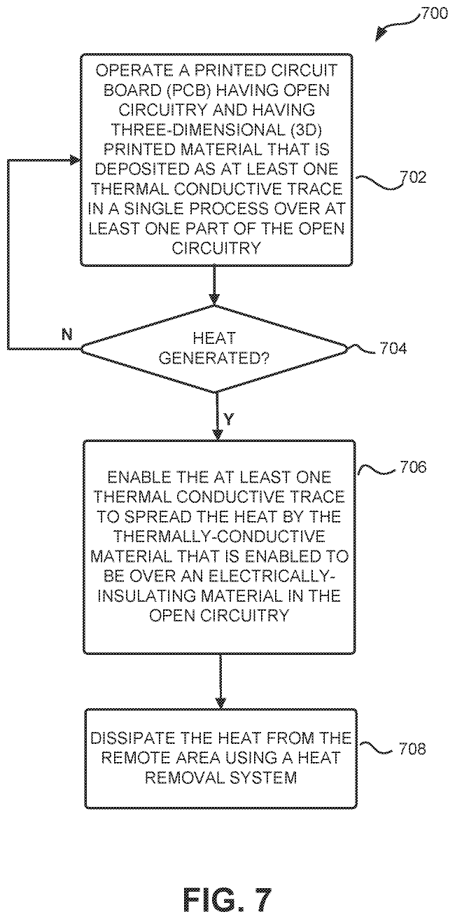

FIG. 7 illustrates a further process flow or method 700 for operating a PCB having a heat spreader by MM3D printing of thermal conductive traces, according to at least one embodiment. The method 700 of FIG. 7 may be used with the method 500 of FIG. 5 or the method 600 of FIG. 6. For example, the method 700 is for a PCB having open circuitry and having MM3D printed material that is deposited as at least one thermal conductive trace in a single process over at least one part of the PCB, and further, the MM3D printed material has an electrically-insulating material and a thermally-conductive material. Therefore, the method 600 may be a method for operating a PCB having open circuitry and having 3D printed material thereon. The method 700 includes operating 702 the PCB to generate heat from the at least one hot area. This step 702 may correspond to the operating 510 step in FIG. 5.

The method 700 may include verifying 704 that heat is being generated. For example, at least one thermal conductive trace can transfer heat in-plane once a temperature at a hot area is higher than a neighboring area to enable a differential temperature heat movement to occur. The method 700 includes enabling 706 the at least one thermal conductive trace to spread heat by the thermally-conductive material in at least one part of the PCB. The thermally-conductive material is enabled to be over the electrically-insulating material of the 3D printed material in an open circuitry of the PCB. This prevents electrical shorting but allows thermal transfer. Therefore, the at least one thermal conductive trace is to spread the heat from at least one hot area of the PCB to a remote area of the PCB. Further, dissipation 708 of heat from the remote area may be performed using a heat removal system. One or more steps 702-708 of the method 700 in FIG. 7 may correspond to the operating 510 step of the semiconductor product, according to the method 500 of FIG. 5. In at least one embodiment, the method 700 in FIG. 7 may include a further step or sub-step of enabling a surface area of the heat to be expanded by the remote area or the at least one thermal conductive trace. For example, based in part on a predetermined temperature of the thermal conductive trace, the heat begins to transfer in-plane.

In the following description, numerous specific details are set forth to provide a more thorough understanding of at least one embodiment. However, it will be apparent to one skilled in the art that the inventive concepts may be practiced without one or more of these specific details.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A printed circuit board (PCB) comprising open circuitry and comprising a three-dimensional (3D) printed material that is deposited in a single process over at least one area of the PCB, the 3D printed material comprising at least a thermally-conductive material to enable at least one thermal conductive trace by the thermally-conductive material being over an electrically-insulating material of the 3D printed material and being over the open circuitry, wherein the at least one thermal conductive trace is to provide heat spreading from at least one hot area of the PCB to a remote area of the PCB.

2. The PCB of claim 1, wherein the thermal conductive trace comprises the thermally-conductive material along with the electrically-insulating material, from the single process, over areas of the PCB that comprise the open circuitry.

3. The PCB of claim 1, wherein the remote area and the at least one thermal conductive trace are to expand a surface area of the heat spreading or are to allow heat dissipation using a heat removal system.

4. The PCB of claim 1, wherein the thermal conductive trace is conformal over one or more features that includes non-planar surfaces and embedded components within planar surfaces on the PCB.

5. The PCB of claim 1, wherein the electrically-insulating material of the single process is over at least one electrically-conductive feature of the open circuitry, with the thermally-conductive material being over the electrically-insulating material, and wherein the thermally-conductive material of the single process is over at least one non-electrically conductive feature of the PCB and is devoid of the electrically-insulating material there under.

6. The PCB of claim 1, further comprising:
at least one heat sink associated with the at least one thermal conductive trace, wherein the at least one heat sink is printed of the thermally-conductive material and is devoid of the electrically-insulating material in the single process.

7. The PCB of claim 1, further comprising:
an insulating polymer or non-polymer to form the electrically-insulating material and a conductive particle composite to form the thermally-conductive material.

8. A method for manufacturing a printed circuit board (PCB) comprising open circuitry, the method comprising:
determining at least one hot area and a remote area of the PCB;
providing the PCB in a 3D printer which comprises an electrically-insulating material and a thermally-conductive material to be provided in a single process;
printing, using the 3D printer and as part of the single process, at least one thermal conductive trace using the 3D printed material, wherein the thermally-conductive material is part of the at least one thermal conductive trace and is enabled to be over the electrically-insulating material in at least one area of the open circuitry, and wherein the at least one thermal conductive trace is to provide heat spreading from the at least one hot area of the PCB to the remote area of the PCB.

9. The method of claim 8, wherein the thermal conductive trace comprises the thermally-conductive material along with the electrically-insulating material, from the single process, over areas of the PCB that comprise the open circuitry.

10. The method of claim 8, wherein the remote area and the at least one thermal conductive trace are to expand a surface area of the heat spreading or are to allow heat dissipation using a heat removal system.

11. The method of claim 8, wherein the thermal conductive trace is conformal over one or more features that includes non-planar surfaces and embedded components within a planar surface on the PCB.

12. The method of claim 8, further comprising:
printing, using the 3D printer and as part of the single process, the electrically-insulating material over at least one electrically-conductive feature of the open circuitry, with the thermally-conductive material being over the electrically-insulating material; and
printing, using the 3D printer and as part of the single process, the thermally-conductive material over at least one non-electrically conductive feature of the PCB, with the thermally-conductive material being devoid of the electrically-insulating material there under.

13. The method of claim 8, further comprising:
printing, using the 3D printer and as part of the single process, at least one heat sink that is associated with the at least one thermal conductive trace, wherein the at least one heat sink is comprised of the thermally-conductive material and is devoid of the electrically-insulating material in the single process.

14. The method of claim 8, further comprising:
providing an insulating polymer or non-polymer adapted for printing from the 3D printer to form the electrically-insulating material; and
providing a conductive particle composite in the 3D printer to form the thermally-conductive material, wherein the 3D printer is adapted to switch between the electrically-insulating material and the electrically-insulating material based in part on features on the PCB that comprises the open circuitry.

15. A three-dimensional (3D) printer configured to receive an electrically-insulating material and a thermally-conductive material to be applied as a 3D printed material in a single process, the 3D printed material forming a thermal conductive trace on a printed circuit board (PCB), wherein the thermal conductive trace comprises the thermally-conductive material that is enabled to be over the electrically-insulating material for at least open circuitry on the PCB, and wherein the at least one thermal conductive trace is to provide heat spreading from at least one hot area of the PCB to a remote area of the PCB.

16. The 3D printer of claim 15, further comprising:
a controller module to control application of the electrically-insulating material and the thermally-conductive material based in part on a design comprising the at least one hot area and the remote area provided for the PCB.

17. The 3D printer of claim 15, the thermal conductive trace comprises the thermally-conductive material along with the electrically-insulating material, from the single process, over areas of the PCB that comprise the open circuitry.

18. The 3D printer of claim 15, wherein the remote area and the at least one thermal conductive trace are to expand a surface area of the heat spreading or are to allow heat dissipation using a heat removal system.

19. A method for operating a printed circuit board (PCB) which comprises open circuitry and comprises three-dimensional (3D) printed material that is deposited as at least one thermal conductive trace in a single process over at least one part of the PCB, the 3D printed material comprising an electrically-insulating material and a thermally-conductive material, the method comprising:
operating the PCB to generate heat; and
enabling the at least one thermal conductive trace to spread heat by the thermally-conductive material in at least one part of the PCB, wherein the thermally-conductive material is enabled to be over the electrically-insulating material of the 3D printed material in an open circuitry of the PCB, and wherein the at least one thermal conductive trace is to spread the heat from at least one hot area of the PCB to a remote area of the PCB.

20. The method of claim 19, further comprising:
enabling a surface area of the heat to be expanded by the remote area or the at least one thermal conductive trace; or
using a heat removal system to perform dissipation of the heat from the PCB.
